(19) United States
(12) Patent Application Publication
(10) Pub. No.: US 2013/0277650 A1
(43) Pub. Date: Oct. 24, 2013

(54) SIGNAL TRANSMISSION UNIT, DISPLAY UNIT, AND ELECTRONIC APPARATUS

(71) Applicant: SONY CORPORATION, Tokyo (JP)

(72) Inventors: Nobuhide Yoneya, Kanagawa (JP); Akira Yumoto, Kanagawa (JP); Ryouichi Yasuda, Kanagawa (JP)

(73) Assignee: SONY CORPORATION, Tokyo (JP)

(21) Appl. No.: 13/850,377

(22) Filed: Mar. 26, 2013

(30) Foreign Application Priority Data
Apr. 18, 2012 (JP) 2012-094562

(51) Int. Cl. H01L 27/32

(52) U.S. Cl. CPC H01L 27/3276
USPC 257/40

(57) ABSTRACT

An electronic apparatus (for example a display unit) including an active region (for example a display region) and a peripheral region. In the active region are disposed: active units (for example pixel circuit), a first wiring line connected to an active unit, a second wiring line connected to an active unit, and a third wiring line disposed in a different layer than the second wiring line and connected to the second wiring line. The first wiring line and the third wiring line extend out of the active region into the peripheral region, and exit the display region on a same side of the display region. A first peripheral circuit for communicating with the first wiring line and a second peripheral circuit for communicating with the second wiring line are disposed in the peripheral region, and the third wiring line is connected to the second peripheral circuit.

### BACKGROUND

The technology relates to a signal transmission unit, a display unit, and an electronic apparatus each having, for example, a plurality of unit regions arranged in a matrix, and performing at least one of input and output of signals.

In a flat-type display unit such as a liquid-crystal display unit and an electrophoretic display unit, a plurality of pixels arranged in a matrix and a plurality of wirings controlling each pixel (for example, a signal line and a scanning line) are provided in a display region on a substrate. The signal line and the scanning line are disposed to be orthogonal to each other, and are connected to a signal-line driving circuit and a scanning-line driving circuit, respectively, which are provided in a peripheral region outside the display region (see, for example, Japanese Unexamined Patent Application Publication Nos. 2006-3741, H06-148671, and 2010-266849). In a rectangular display unit, for example, a signal line and a scanning line may extend in a column direction and a row direction, respectively, and a signal-line driving circuit and a scanning-line driving circuit may be provided at a long side and a short side, respectively.

### SUMMARY

When the signal line and the scanning line, which are orthogonal to each other as described above, exit the display region in their respective extending directions (i.e., they exit the display region in orthogonal directions), spaces for the signal-line driving circuit and the scanning-line driving circuit must be allocated along two sides of the display region (for example, a long side and a short side) in a peripheral region. In other words, there has been such a disadvantage that a large bezel region (a peripheral region) is formed along two directions.

It is desirable to provide a signal transmission unit, a display unit, and an electronic apparatus which are capable of reducing a size of a bezel.

According to an aspect of an exemplary embodiment of the present disclosure, there may be provided a display unit including a display region in which are disposed, pixel circuits, a first wiring line connected to a given one of the pixel circuits, a second wiring line connected to the given one of the pixel circuits, and a third wiring line disposed in a different layer than the second wiring line and connected to the second wiring line. The display unit may also include a peripheral region, with the first wiring line and the third wiring line extending out of the display region into the peripheral region.

According to another aspect of the above-described exemplary embodiment, a first peripheral circuit for communicating with the first wiring line and a second peripheral circuit for communicating with the second wiring line may be disposed in the peripheral region. Further, the first wiring line may be connected to the first peripheral circuit and the third wiring line may be connected to the second peripheral circuit.

According to another aspect of the above-described exemplary embodiment, the third wiring line and the first wiring line may exit the display region on a same side of the display region.

According to another aspect of the above-described exemplary embodiment, the third wiring line and the first wiring line may extend in directions substantially parallel to each other as they exit the display region.

According to another aspect of the above-described exemplary embodiment, the first wiring line may be a signal line that provides a video signal to the given one of the pixel circuits and the second wiring line may be a scanning line that provides a scanning signal for controlling introduction of the video signal into the given one of the pixel circuits.

According to another aspect of the above-described exemplary embodiment, the second wiring line may be a signal line that provides a video signal to the given one of the pixel circuits and the first wiring line may be a scanning line that provides a scanning signal for controlling introduction of the video signal into the given one of the pixel circuits.

According to another aspect of the above-described exemplary embodiment, the first wiring line may be a signal line that provides a video signal to the given one of the pixel circuits and the second wiring line may be a gate electrode of a transistor of the given one of the pixel circuits.

According to another aspect of the above-described exemplary embodiment, the first wiring line may extend from the peripheral region towards the display region in a first direction. Further, the third wiring line may extend from the peripheral region towards the display region in the first direction, then, in the display region, may turn to extend in a second direction perpendicular to the first direction.

According to another aspect of the above-described exemplary embodiment, the second wiring line may extend in the display region in the second direction and may be connected to the third wiring line via a connection hole located at a side of the display region that is different from the side of the display region through which the first wiring line exits the display region.

According to another aspect of the above-described exemplary embodiment, the first wiring line may extend from a first peripheral circuit towards the display region in a first direction. Further, the third wiring line may extend from a second peripheral circuit towards the display region in the first direction, and then, in the display region, may turn to extend in a second direction perpendicular to the first direction.

According to another aspect of the above-described exemplary embodiment, the first peripheral circuit and the second peripheral circuit may be disposed in a portion of the peripheral region that is adjacent to a same side of the display region. Further, the portion of the peripheral region in which the first peripheral circuit and the second peripheral circuit are disposed may be adjacent to a longitudinal side of the display device. Alternatively, the portion of the peripheral region in which the first peripheral circuit and the second peripheral circuit are disposed may be adjacent to a short side of the display device.

According to another aspect of the above-described exemplary embodiment, the display unit is a flexible display unit.

According to another aspect of the above-described exemplary embodiment, the given one of the pixel circuits may include an organic light emitting element, a storage capacitor, a drive transistor for providing a driving current to the organic light emitting element whose current depends on a potential stored in the storage capacitor, and a write transistor for writing a signal potential into the storage capacitor. Further, one of the first wiring line and the second wiring line may be connected to a gate electrode of the write transistor and the other one of the first wiring line and the second wiring line may be connected to a current electrode of the write transistor.

According to another aspect of the above-described exemplary embodiment, the third wiring line may disposed on a substrate, an insulating layer may be disposed on the third wiring line, the second wiring line may be disposed on the insulating layer and connected to the third wiring line via a connection hole, a second insulating layer may be disposed on the second wiring line, the first wiring line may be disposed on the second insulating layer, the pixel circuits may be disposed on the second insulating layer in the display region and the given one of the pixel circuits may be connected to the second wiring line and the first wiring line, the first peripheral circuit and the second peripheral circuit may be disposed on the substrate in the peripheral region adjacent the display region, and the first wiring line may be connected to the first peripheral circuit and the third wiring line may be connected to the second peripheral circuit.

According to an aspect of another exemplary embodiment of the present disclosure, an electronic apparatus may be provide, including an active region in which are disposed active units, a first wiring line connected to a given one of the active units, a second wiring line connected to the given one of the active units, and a third wiring line disposed in a different layer than the second wiring line and connected to the second wiring line. The electronic apparatus may further include a peripheral region, and the first wiring line and the third wiring line may extend out of the active region into the peripheral region.

According to another aspect of the above-described exemplary embodiment, the active region may be a touch panel input region, the active units may be positional information detection units configured to detect a position of an input device, and the first peripheral circuit and the second peripheral circuit may be sensor circuits.

According to an aspect of another exemplary embodiment of the present disclosure, there is provided a signal transmission unit including: a first wiring extending in a first direction; a second wiring provided in a layer different from a layer in which the first wiring is provided; and a third wiring provided in a layer different from the layer in which the second wiring is provided. The third wiring is electrically connected to the second wiring, and at least a part of the third wiring extends in the first direction.

According to an aspect of another exemplary embodiment of the present disclosure, there is provided a display unit with a display section and a signal transmission unit. The signal transmission unit includes: a first wiring extending in a first direction; a second wiring provided in a layer different from a layer in which the first wiring is provided; and a third wiring provided in a layer different from the layer in which the second wiring is provided. The third wiring is electrically connected to the second wiring, and at least a part of the third wiring extends in the first direction.

According to an aspect of another exemplary embodiment of the present disclosure, there is provided an electronic apparatus with a signal transmission unit. The signal transmission unit includes: a first wiring extending in a first direction; a second wiring provided in a layer different from a layer in which the first wiring is provided; and a third wiring provided in a layer different from the layer in which the second wiring is provided. The third wiring is electrically connected to the second wiring, and at least a part of the third wiring extends in the first direction.

According to the above-described exemplary embodiments of the present disclosure, the third wiring may be provided in a different layer than the second wiring line. This makes it possible for the first wiring and the third wiring to exit the display region/active region in the same direction. Therefore, the number of exit directions is reduced, making it possible to reduce a size of a bezel.

It is to be understood that both the foregoing general description and the following detailed description are exemplary, and are intended to provide further explanation of the technology as claimed.

### BRIEF DESCRIPTION OF THE DRAWINGS

The accompanying drawings are included to provide a further understanding of the disclosure, and are incorporated in and constitute a part of this specification. The drawings illustrate embodiments and, together with the specification, serve to describe the principles of the technology.

FIGS. 1A to 1C are diagrams each illustrating a configuration of a display unit according to a first embodiment of the disclosure.

FIGS. 2A and 2B are diagrams each illustrating a configuration of a display region illustrated in FIG. 1A.

FIGS. 3A and 3B are diagrams each illustrating an example of a configuration of a pixel driving circuit included in a wiring layer illustrated in FIG. 2B.

FIG. 4 is a plan view illustrating a configuration of a leading line illustrated in FIGS. 1B and 1C.

FIGS. 5A to 5C are diagrams illustrating a method of manufacturing a TFT substrate illustrated in FIG. 1A.

FIGS. 6A to 6C are diagrams illustrating a process following the process illustrated in FIGS. 5A to 5C.

FIGS. 7A to 7C are diagrams illustrating a process following the process illustrated in FIGS. 6A to 6C.

FIGS. 8A to 8C are diagrams each illustrating a configuration of a TFT substrate according to a comparative example.

FIGS. 9A and 9B are plan views each illustrating a configuration of a TFT substrate according to a modification 1.

FIGS. 10A and 10B are diagrams each illustrating a configuration of one pixel of a TFT substrate according to a modification 2.

FIGS. 11A and 11B are diagrams each illustrating a configuration of one pixel of the TFT substrate illustrated in FIG. 8A according to the comparative example.

FIGS. 12A and 12B are diagrams illustrating another example of the TFT substrate illustrated in FIGS. 10A and 10B.

FIGS. 13A to 13C are diagrams each illustrating a configuration of a display unit according to a second embodiment of the disclosure.

FIGS. 14A and 14B are diagrams each illustrating a configuration of one pixel of a TFT substrate according to a modification 3.

FIGS. 15A and 15B are perspective diagrams each schematically illustrating an appearance of an application example 1.

FIG. 16 is a perspective diagram schematically illustrating an appearance of an application example 2.

FIGS. 17A and 17B are perspective diagrams each schematically illustrating an appearance of an application example 3, namely, FIG. 17A illustrates the appearance when viewed from front, and FIG. 17B illustrates the appearance when viewed from back.

FIG. 18 is a perspective diagram schematically illustrating an appearance of an application example 4.

FIG. 19 is a perspective diagram schematically illustrating an appearance of an application example 5.

FIGS. 20A to 20G are schematic views of an application example 6, namely, a front view in an open state, a side view in the open state, a front view in a closed state, a left-side view, a right-side view, a top view, and a bottom view, respectively.

FIG. 21 is a diagram illustrating a configuration of a signal transmission unit according to another embodiment of the disclosure.

### DETAILED DESCRIPTION

Example embodiments of the technology will be described in detail with reference to the drawings.

It will be understood that if a first item (for example, a layer) is recited as being “disposed on” a second item (for example, another layer, etc.), then the first item is located above the second item in a stacking direction, but that this does not preclude other items being disposed between the first item and the second item. If the first item is recited as being “disposed directly on” the second item, then there are no items disposed between the first and second items in the stacking direction.

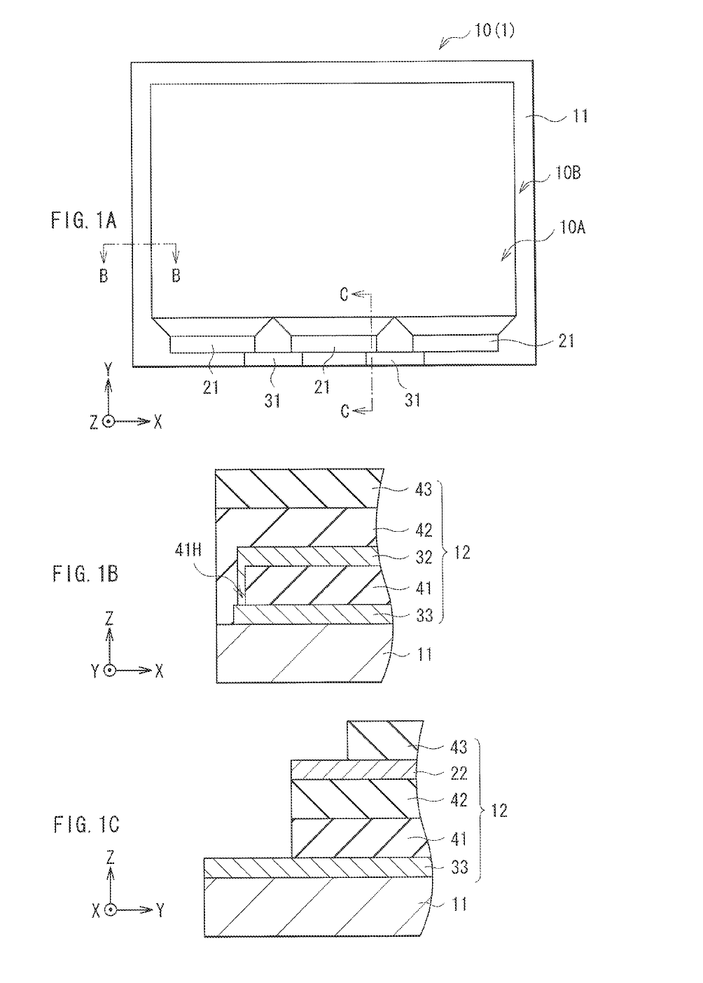

It will also be understood that the term “layer” has both a specific meaning and a general meaning. According to the specific meaning, a layer is a single thickness of something that lies over or under something or between other similar thicknesses. According to the general meaning, multiple layers that are discrete layers according to the specific meaning and that are sandwiched together may be considered a single layer for certain purposes. For example, the layers 33, 41, 32, 42, 22, and 43 as illustrated in FIGS. 1B-C are referred to collectively as the wiring layer 12 according the general meaning of “layer”. Similarly an organic luminous layer of an organic EL (Electroluminescence) device may be referred to as a single layer according the general meaning of “layer”, and yet may comprise multiple layers of different materials sandwiched together.

However, when it is recited that one item is in a “same layer” as or “different layer” than another item, it will be understood that the specific meaning of the term “layer” is meant, unless specifically noted otherwise. In particular, when one wiring line is recited as being in a “same layer” as another wiring line, then the wiring lines are both disposed directly on the same layer with no insulating layers being disposed therebetween in a stacking direction. Furthermore, when one wiring line is recited as being in a “different layer” from another wiring line, then the wiring lines are directly disposed on different layers with at least one insulating layer is disposed therebetween in a stacking direction.

It is to be noted that the description will be provided in the following order.

### 1. First Embodiment

A display unit in which a scanning line (a second wiring) is electrically connected to a leading line (a third wiring)

### 2. Modification 1

A display unit in which a scanning-line driving circuit and a signal-line driving circuit are aligned

### 3. Modification 2

A display unit in which a gate electrode (a second wiring) of a TFT is electrically connected to a leading line (a third wiring)

### 4. Second Embodiment

A display unit in which a signal line (a second wiring) is electrically connected to a leading line (a third wiring)

### 5. Modification 3

A display unit in which a source-drain electrode (a second wiring) of a TFT is electrically connected to a leading line (a third wiring)

### First Embodiment

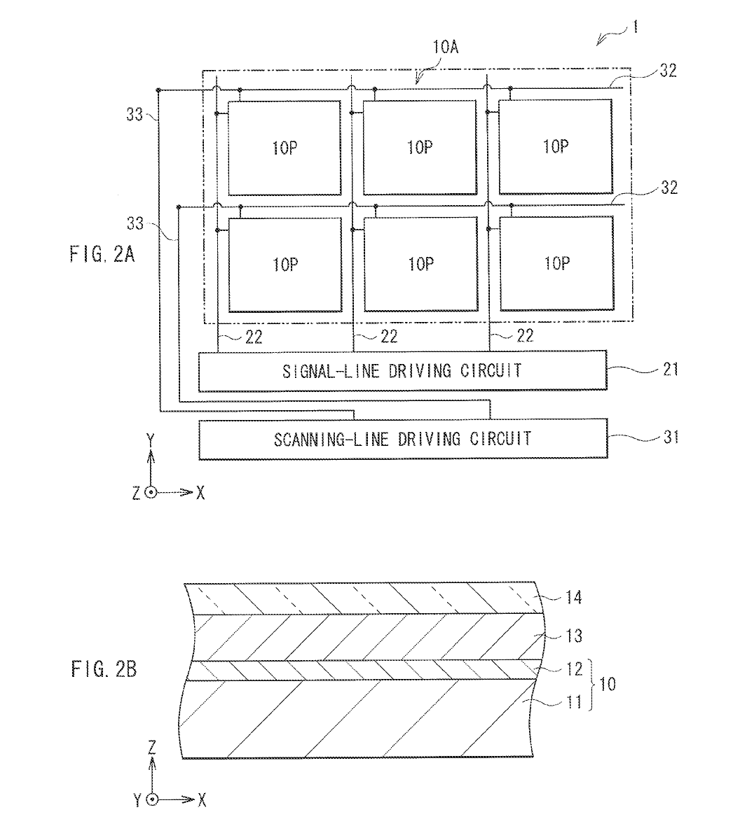

FIGS. 1A to 1C each illustrate a configuration of a TFT substrate (a TFT substrate 10) of a display unit 1 (a signal transmission unit) according to a first embodiment of the disclosure. FIGS. 1A to 1C also illustrate a signal-line driving circuit 21 (a first peripheral circuit) and a scanning-line driving circuit 31 (a second peripheral circuit) which are drivers for image display. FIG. 1A illustrates a plane configuration, FIG. 1B illustrates a cross-sectional configuration taken along a line B-B of FIG. 1A, and FIG. 1C illustrates a cross-sectional configuration taken along a line C-C of FIG. 1A. The display unit 1 may include, as illustrated in FIGS. 2A and 2B, a display layer 13 and a transparent substrate 14 on the TFT substrate 10 (FIG. 2B), and a plurality of pixels 10P (unit regions) may be arranged in a matrix in a display region 10A (a signal transmission section) at a central part (FIG. 2A). FIG. 2A and FIG. 2B schematically illustrates a plane configuration and a cross-sectional configuration, respectively, of the entire display unit 1. The signal-line driving circuit 21 (the first peripheral circuit) and the scanning-line driving circuit 31 (the second peripheral circuit) may be provided in a peripheral region 10B around the display region 10A (FIG. 1A and FIG. 2A).

The TFT substrate 10 includes a substrate 11 and a wiring layer 12 (FIG. 1B and FIG. 1C). The substrate 11 may be, for example, rectangular, and may be made of an inorganic material such as glass, quartz, silicon, gallium arsenide, and metallic foil. The substrate 11 may be alternatively made of a plastic material such as polyimide, polyethylene terephthalate (PET), polyethylene naphthalate (PEN), polymethyl methacrylate (PMMA), polycarbonate (PC), polyether sulfone (PES), polyether ether ketone (PEEK), and aromatic polyester (liquid crystal polymer). The substrate 11 may be made of other suitable material other than the materials described above. The substrate 11 may be a rigid substrate such as wafer, or may be a flexible substrate such as lamina glass, lamina ceramic, and film. In one embodiment where the substrate 11 is a flexible substrate, it is possible to achieve a bendable display unit, i.e., a so-called flexible display.

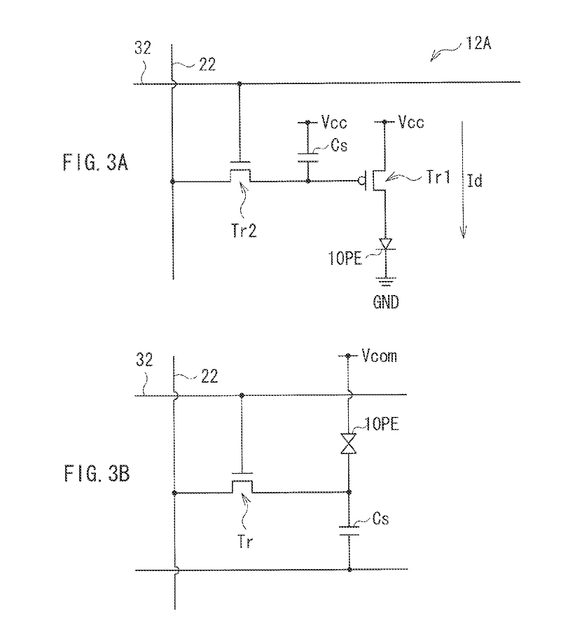

In the display region 10A of the wiring layer 12, a TFT (for example, a drive transistor Tr1 in FIGS. 3A and 3B which will be described later) serving as a switching device is provided for each of the pixels 10P to select the corresponding pixel 10P. The TFT may include, for example, a gate electrode, a channel layer, and a pair of source-drain electrodes. The channel layer may be either an inorganic semiconductor layer or an organic semiconductor layer. Further, in the wiring layer 12, a plurality of scanning lines 32 (a second wiring) are provided to extend in an X direction (a second direction), and a plurality of signal lines 22 (a first wiring) provided to extend in a Y direction (a first direction) (FIG. 2A). As will be described later, the scanning lines 32 are provided in a layer different from that of the signal lines 22. It is to be noted that the X direction and the Y direction may intersect each other, specifically, at substantially right angles. The gate electrode of the TFT and one of the source-drain electrodes may be electrically connected to the scanning line 32 and the signal line 22, respectively, for example. The pixel 10P is disposed at the intersection of the scanning line 32 and the signal line 22. The scanning lines 32 and the signal lines 22 may be electrically connected to the scanning-line driving circuit 31 and the signal-line driving circuit 21, respectively.

FIG. 3A illustrates an example of a pixel driving circuit 12A provided in the wiring layer 12. The pixel driving circuit 12A includes the drive transistor Tr1 as well as a write transistor Tr2, a capacitor (a retention capacitor) Cs provided between these transistors Tr1 and Tr2, and a device 10PE connected to the drive transistor Tr1 in series between a first power source line (Vcc) and a second power source line (GND). The pixel driving circuit 12A may include the drive transistor Tr1, the capacitor (the retention capacitor) Cs, and the device 10PE, without including the write transistor Tr2, as illustrated in FIG. 3B.

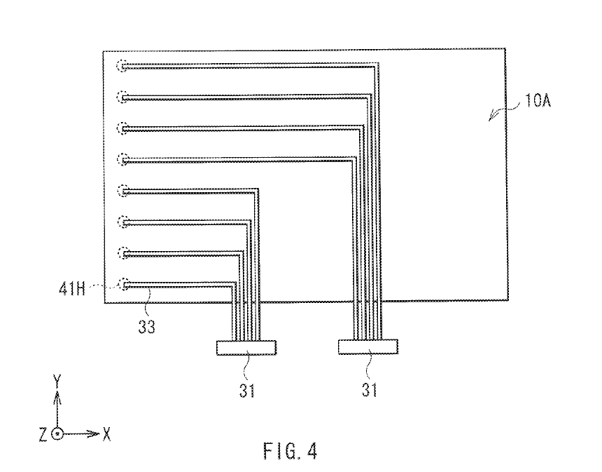

In the present embodiment, the scanning line 32 is electrically connected to a wiring (a leading line 33) provided in a layer different from that of the scanning line 32, and may be connected to the scanning-line driving circuit 31 through the leading line 33 (a third wiring). This makes it possible to reduce a size of a bezel, by having the leading line 33 (which is connected to the scanning line 32) and the signal line 22 exit the display region in the same taken-out directions. The wiring layer 12 may include the leading line 33, a first interlayer insulating film 41 (a first insulating film), the scanning line 32, a gate insulating film 42 (a second insulating film), the signal line 22, and a second interlayer insulating film 43 in this order on the substrate 11. The scanning line 32 may be electrically connected to the leading line 33 through a connection hole 41H of the first interlayer insulating film 41 provide in the peripheral region 10B (FIGS. 1B and 1C). The connection holes 41H may be provided, for example, along a short side (for example, a left side) of the substrate 11 (FIG. 4 which will be described later).

As illustrated in FIG. 4, the leading line 33 may be bent in the Y direction (a downward direction on a sheet surface of the figure), after being extended from the connection hole 41H in the X direction. Therefore, at one side (a long side in a lower part of the sheet surface) of the substrate 11, the leading line 33 extends in the Y direction, and exits the display region together with the signal line 22 at a lower side of the display region. This makes it possible to dispose the scanning-line driving circuit 31 and the signal-line driving circuit 21 at one side of the TFT substrate 10 (the substrate 11). Thus, a space for the scanning-line driving circuit 31 and the signal-line driving circuit 21 need only be allocated on one side of the display region. Therefore, the bezel on the side of the display region in which the scanning-line driving circuit 31 would have otherwise been disposed may be reduced.

Wirings such as the signal line 22, the scanning line 32, and the leading line 33 may be each made of, for example, a metal such as aluminum (Al), molybdenum (Mo), titanium (Ti), copper (Cu), chromium (Cr), gold (Au), silver (Ag), and tantalum (Ta), or a transparent conductor such as ITO (Indium-Tin-Oxide), IGO (Indium-Gallium-Oxide), and IGZO (Indium-Gallium-Zinc-Oxide). These wirings may be each made of an organic conductive material such as PEDOT/PSS and polyaniline. The first interlayer insulating film 41, the gate insulating film 42, and the second interlayer insulating film 43 may be each made of an organic insulating material or an inorganic insulating material such as silicon oxide (SiO_{X}), silicon nitride (SiN), and aluminum oxide (Al₂O₃). The organic insulating material may be, for example but not limited to, a material in which a melamine-based cross-linker is added to PVP (polyvinylphenol). The first interlayer insulating film 41 may have a thickness (a thickness in a lamination direction (a Z direction), which will be hereinafter simply referred to as “thickness”) of, for example, about 0.5 μm to about 10 μm both inclusive. The gate insulating film 42 may have a thickness of, for example, about 300 nm to about 1 μm both inclusive, and the second interlayer insulating film 43 may have a thickness of, for example, about 0.5 μm to about 10 μm both inclusive.

The signal-line driving circuit 21 supplies the pixel 10P selected through the signal line 22, with a signal voltage of an image signal according to luminance information supplied from a signal supply source (not illustrated). The scanning-line driving circuit 31 may be configured using, for example, elements such as a shift register that sequentially shifts (transmits) a start pulse in synchronization with an input clock pulse. When writing the image signal to each of the pixels 10P, the scanning-line driving circuit 31 scans them row by row, and sequentially supplies a scanning signal to each of the scanning lines 32 (the leading lines 33). The signal-line driving circuit 21 and the scanning-line driving circuit 31 may be each made of, for example, a driver chip. In the display unit 1, the signal-line driving circuit 21 and the scanning-line driving circuit 31 may be gathered at a long side of the TFT substrate 10. Here, the signal-line driving circuit 21 and the scanning-line driving circuit 31 may be provided in a displaced fashion with respect to each other, and the scanning-line driving circuit 31 may be disposed further outward of (below) the display region 10A than the signal-line driving circuit 21.

A barrier layer (not illustrated) may be provided between the substrate 11 and the wiring layer 12, in order to prevent deterioration, due to factors such as water and organic gas, of the wiring layer 12 and the display layer 13. The barrier layer may be formed, for example, of a material such as AlO_{X}N_{1-X} (where X=0.01 to 0.2 both inclusive) and silicon nitride (Si₃N₄).

The display layer 13 on the TFT substrate 10 may be configured using, for example, an organic EL (Electroluminescence) device which may have, for example, an organic luminous layer between a pixel electrode and a common electrode. The pixel electrode may be provided on the wiring layer 12 for each of the pixels 10P, for example, and the common electrode may be provided over one surface of the transparent substrate 14. It is to be noted that the display layer 13 is not limited to an organic EL-based configuration, and the display layer 13 may have a configuration in which a layer such as an inorganic luminous layer, an electrophoretic layer, and a liquid crystal layer is provided between the pixel electrode and the common electrode.

In the display unit 1, an image is displayed on a side where the transparent substrate 14 is provided. A material similar to that of the substrate 11 may be used for the transparent substrate 14. On the transparent substrate 14, there may be further provided a film such as a moisture-proof film preventing entry of water into the display layer 13 and an optical function film intended to prevent a glare on a display surface caused by external light.

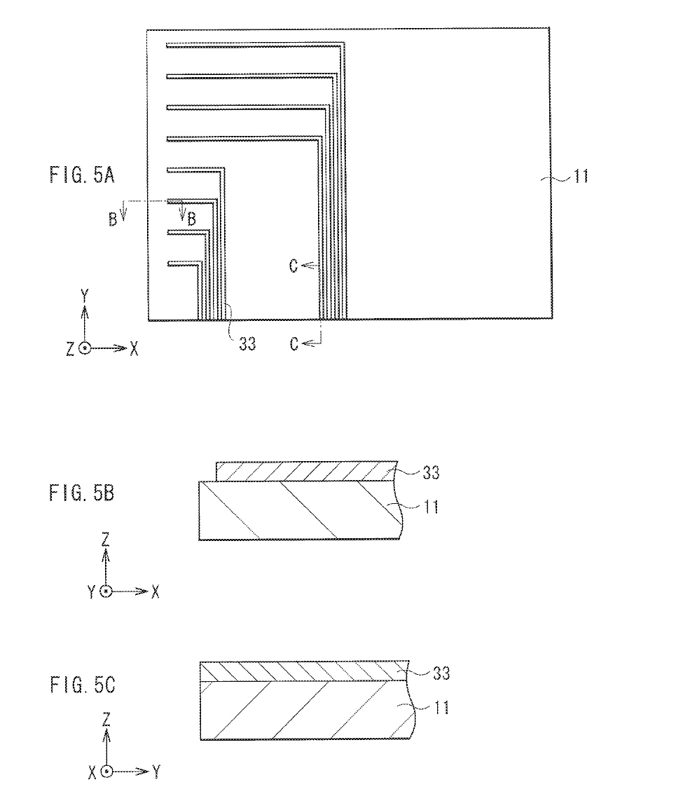

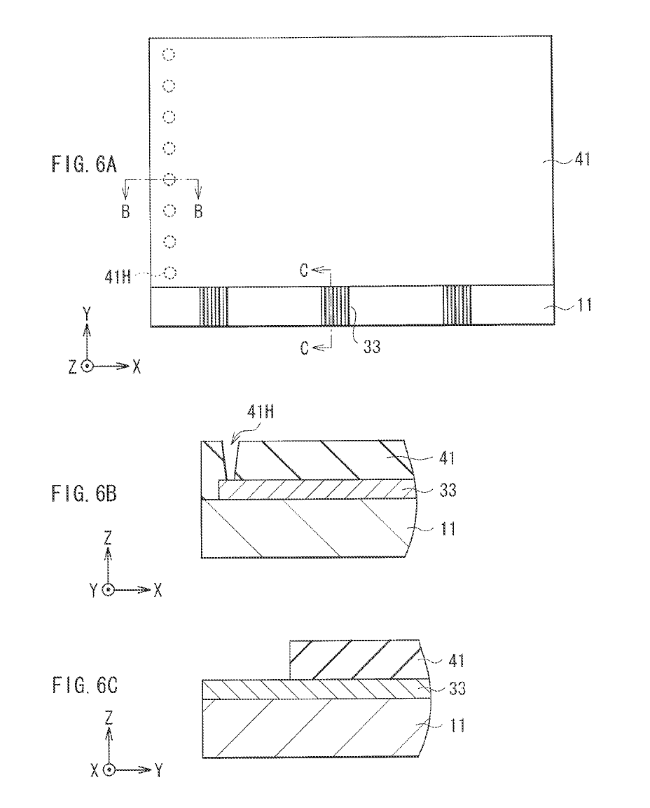

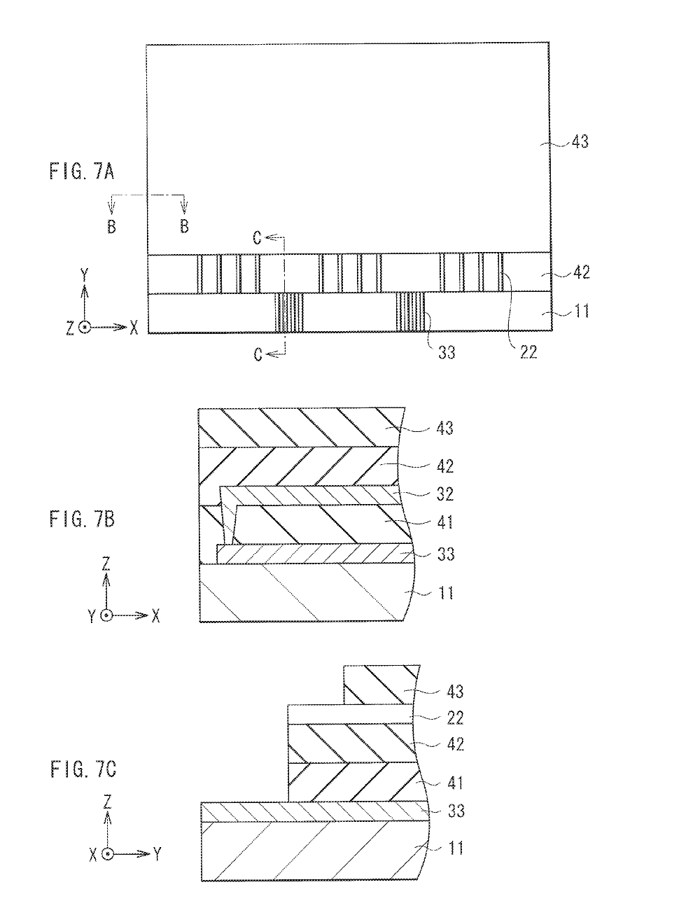

The display unit 1 may be manufactured as follows, for example (FIG. 5A to FIG. 7C). FIG. 5A, FIG. 6A, and FIG. 7A are each a plan view of corresponding process, FIG. 5B, FIG. 6B, and FIG. 7B are each a cross-sectional diagram taken along a line B-B in the corresponding diagram, and FIG. 5C, FIG. 6C, and FIG. 7C are each a cross-sectional diagram taken along a line C-C in the corresponding diagram.

First, the wiring layer 12 is formed on the substrate 11. Specifically, first, a film of a conductive material is formed on the substrate 11, following which the formed conductive material film is patterned using, for example, photolithography to form the leading lines 33 (FIGS. 5A to 5C). The leading lines 33 may extend in the X direction and may be bent to extend in the Y direction. The leading lines 33 may be formed by a printing method such as offset printing, ink jet printing, and screen printing.

Next, for example, the first interlayer insulating film 41 may be formed on the leading lines 33 and the substrate 11. The first interlayer insulating film 41 may be so formed by patterning as to allow an end part (in proximity to a lower side of the substrate 11) of each of the leading lines 33 extending in the Y direction to be exposed (FIG. 6C). In one embodiment where the first interlayer insulating film 41 is made of light photosensitive resin, it is possible to perform patterning by photolithography easily. The first interlayer insulating film 41 may be formed by a printing method, such as one of those described above. Alternatively, the first interlayer insulating film 41 may be formed by, for example, depositing a film of an inorganic insulating material such as silicon oxide, silicon nitride, and aluminum oxide by a method such as sputtering and CVD (Chemical Vapor Deposition). Also, the first interlayer insulating film 41 may be formed by laminating an organic insulating material and an inorganic insulating material.

The connection holes 41H may be formed in the first interlayer insulating film 41, at positions corresponding to the respective leading lines 33. Each of the connection holes 41H may be provided at, for example, a left-end part of the substrate 11.

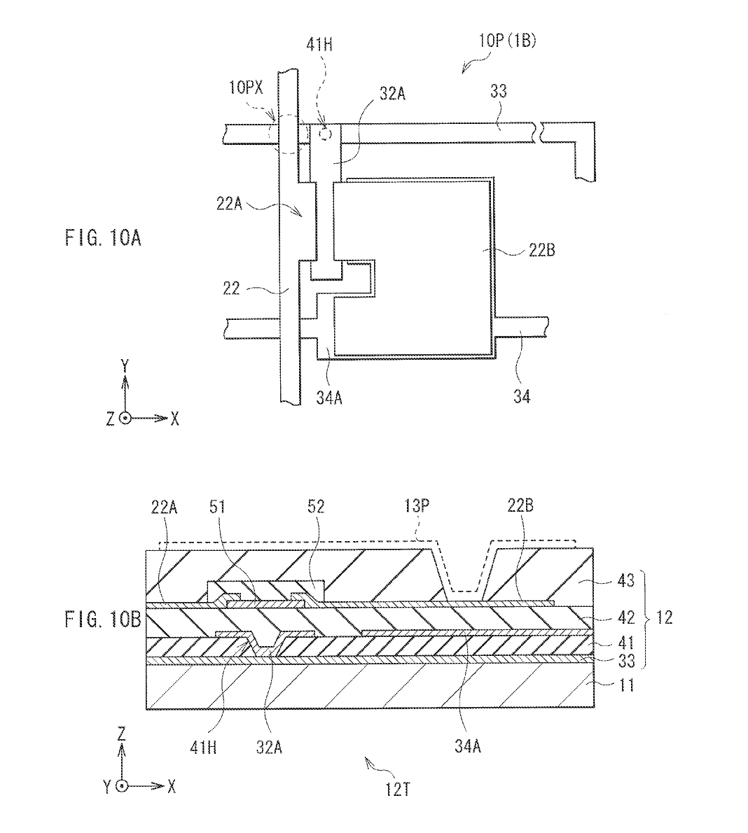

After the connection hole 41H is provided in the first interlayer insulating film 41, each of the scanning lines 32 extending in the X direction is formed on the first interlayer insulating film 41. At this moment, the scanning line 32 may be electrically connected to the leading line 33 through the connection hole 41H. Next, the gate insulating film 42 may be so formed as to expose an end part of the leading line 33 in a manner similar to the first interlayer insulating film 41 on the scanning lines 32, following which the signal lines 22 extending in the Y direction are formed on the gate insulating film 42. Subsequently, the second interlayer insulating film 43 may be so formed on the signal lines 22 by patterning as to allow an end part (in proximity to the lower side of the substrate 11) of the signal line 22 and the end part of the leading line 33 to be exposed (FIG. 7C). Of the signal line 22, the part exposed from the second interlayer insulating film 43 may be provided, for example, more inward than the exposed part of the leading line 33. In the above-described process of forming the wiring layer 12, for example, the gate electrode may be formed together with the scanning line 32, the channel layer (for example, a channel layer 51 in FIGS. 10A and 10B, which will be described later) may be formed on the gate insulating film 42, and the source-drain electrodes (for example, source-drain electrodes 22A and 22B in FIGS. 10A and 10B, which will be described later,) may be formed together with the signal line 22, to provide TFT in the display region 10A.

After the wiring layer 12 is formed, the display layer 13 is formed on the wiring layer 12. Subsequently, the transparent substrate 14 is provided to face the TFT substrate 10, with the display layer 13 interposed between. Finally, the signal-line driving circuit 21 and the scanning-line driving circuit 31 are electrically connected to the exposed signal lines 22 and the exposed leading lines 33, respectively. This completes the display unit 11.

In the display unit 1, an image signal and a scanning signal are supplied from the signal-line driving circuit 21 and the scanning-line driving circuit 31, respectively, to the TFT of the wiring layer 12. Thus, the display layer 13 is controlled for each of the pixels 10P, and an image is displayed on the side where the transparent substrate 14 is provided.

In the display unit 1 of the present embodiment, the leading line 33 electrically connected to the scanning line 32 is provided, and the leading line 33 exits the display region in the same direction as that of the signal line 22. Thus, it is possible to reduce a size of a bezel of the display unit 1, by disposing the scanning-line driving circuit 31 and the signal-line driving circuit 21 at one side of the substrate 11. This will be described below.

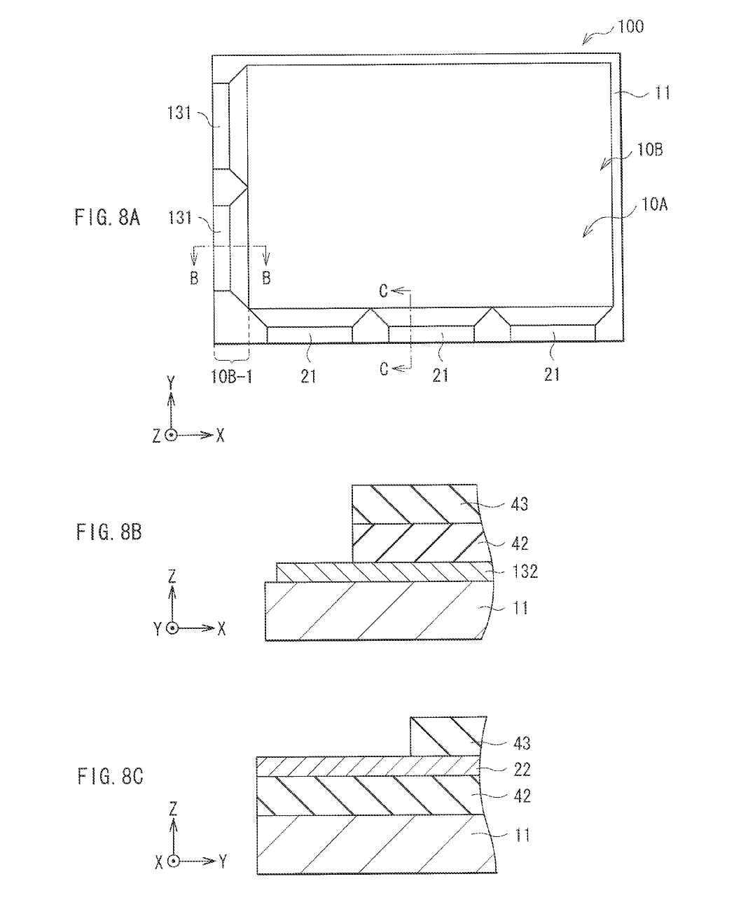

FIGS. 8A to 8C each illustrate a configuration of a TFT substrate (a TFT substrate 100) of a display unit according to a comparative example. FIG. 8A illustrates a plane configuration of the TFT substrate 100, FIG. 8B illustrates a cross-sectional configuration taken along a line B-B of FIG. 8A, and FIG. 8C illustrates a cross-sectional configuration taken along a line C-C of FIG. 8A. Since the TFT substrate 100 does not have a leading line, a scanning line 132 extending in an X direction is connected to a scanning-line driving circuit 131 directly. In other words, a taken-out direction of the scanning line 132 is orthogonal to a signal line 22 (i.e., a direction in which the scanning line 132 exits the display region is orthogonal to the signal line 22), and a space (a peripheral region 10B-1) is necessary in a peripheral region 10B to dispose the scanning-line driving circuit 131. This space (the peripheral region 10B-1) may be provided at a side (for example, a left side) different from and orthogonal to one side (a lower side) of a substrate 11 where a signal-line driving circuit 21 is provided. The TFT substrate 100 thus has the signal-line driving circuit 21 and the scanning-line driving circuit 131 along the two sides, making it difficult to narrow the peripheral region 10B-1. In particular, when configuring a flexible display using the TFT substrate 100, flexibility is impaired by the signal-line driving circuit 21 and the scanning-line driving circuit 131 which are respectively provided at the two sides intersecting at right angles.

Also, a method has been proposed in which a signal line 22 and a scanning line 132 are connected to a flexible cable by ACF (Anisotropic Conductive Film) and are taken out to the outside of a TFT substrate 100. Such a method, however, has low mechanical durability because the ACF is used. Moreover, the number of components increases, which results in deterioration in reliability and yield, besides a disadvantage in terms of cost.

In contrast, in the display unit 1 according to the first embodiment, the scanning line 32 is electrically connected to the leading line 33 provided in a layer lower than that of the scanning line 32, and the leading line 33 exits the display region in the same direction as that of the signal line 22. Therefore, it is possible to gather the scanning-line driving circuit 31 and the signal-line driving circuit 21 at one side of the substrate 11. In other words, the peripheral region 10B-1 of the TFT substrate 100 is unnecessary, making it possible to reduce a size of a bezel.

Further, in one embodiment where the display unit 1 is a flexible display, a bending direction improves, thereby enhancing flexibility. Furthermore, it is possible to suppress the number of components, since it is not necessary to use components such as ACF and a flexible cable in the display unit 1.

In the display unit 1 of the present embodiment as described above, the leading line 33 is provided, and the scanning line 32 is connected to the leading line 33, making it possible to gather the scanning-line driving circuit 31 and the signal-line driving circuit 21 at one side of the substrate 11. Therefore, the peripheral region 10B of the display unit 1 is allowed to be reduced in size. Moreover, flexibility improves in one embodiment where the display unit 1 is a flexible display.

Modifications of the first embodiment and another embodiment will be described below. In the following description, the same components as those of the above-described embodiment will be provided with the same reference numerals as those of the above-described embodiment, and the description thereof will be omitted as appropriate.

### [Modification 1]

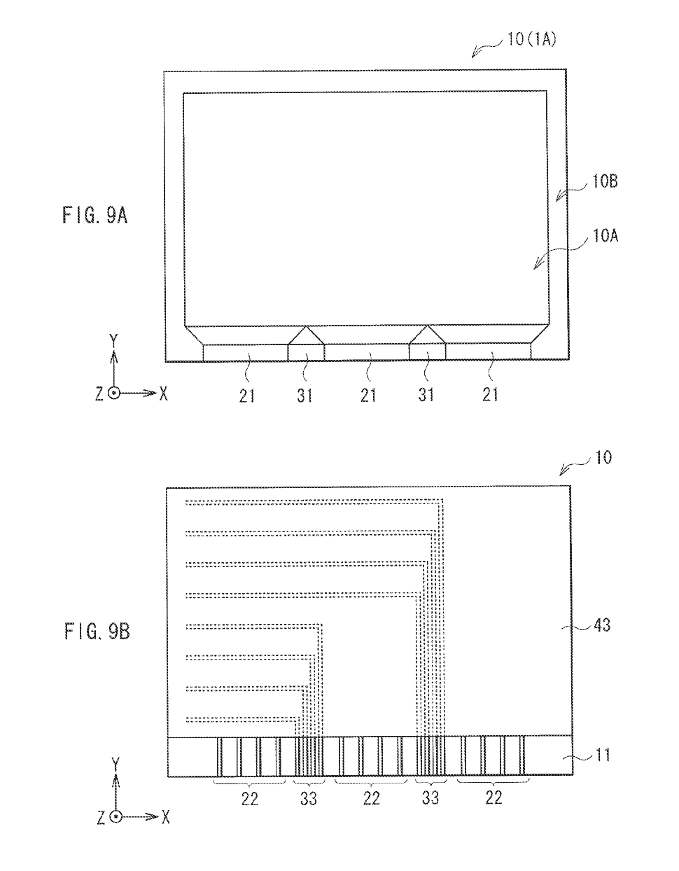

FIG. 9A illustrates a plane configuration of the TFT substrate 10 of a display unit (a display unit 1A) according to a modification 1 of the above-described embodiment, together with the signal-line driving circuit 21 and the scanning-line driving circuit 31. In the display unit 1A, the signal-line driving circuit 21 and the scanning-line driving circuit 31 are aligned along the same line at one side of the substrate 11. Otherwise, the display unit 1A has a configuration, functions, and effects similar to those of the display unit 1 of the first embodiment.

As illustrated in FIG. 9B, the signal line 22 and the leading line 33 exit the display region at the same side of the display unit 1A, extending in the negative Y direction. The signal-line driving circuit 21 and the scanning-line driving circuit 31 are electrically connected to the signal line 22 and the leading line 33, respectively, and are arranged in the X direction. The signal line 22 and the leading line 33 extend below the display region in the negative Y direction substantially the same distance, such that signal-line driving circuit 21 and the scanning-line driving circuit 31 may be aligned along the same line in the X direction. In other words, the signal-line driving circuit 21 and the scanning-line driving circuit 31 are arranged linearly and side-by-side in the X direction with respect to the display region 10A. This makes it possible to narrow one side (for example, the lower side) of the peripheral region 10B of the substrate 11, which allows further achievement in size reduction of a bezel.

### [Modification 2]

FIGS. 10A and 10B each illustrate a configuration of one of pixels 10P of a display unit (a display unit 1B) according to a modification 2 of the above-described embodiment. FIG. 10A and FIG. 10B illustrate a plane configuration and a cross-sectional configuration, respectively. In the display unit 1B, the leading line 33 is electrically connected to a gate electrode (a gate electrode 32A) of a TFT (a TFT 12T) and the leading line 33 is provided for each of the pixels 10P. Otherwise, the display unit 1B has a configuration, functions, and effects similar to those of the display unit 1 of the first embodiment.

In the display unit 1B, the TFT 12T provided for each of the pixels 10P includes: the gate electrode 32A (the second wiring) on the first interlayer insulating film 41; the channel layer 51 facing the gate electrode 32A with the gate insulating film 42 interposed therebetween; and a passivation layer 52 that covers the source-drain electrodes 22A and 22B as well as the channel layer 51 on the gate insulating film 42. On the second interlayer insulating film 43, a pixel electrode 13P of the display layer 13 is so provided as to cover the TFT 12T. In the same layer as that of the gate electrode 32A, a Cs electrode (capacitor electrode) 34A and a Cs line 34 are provided. The Cs electrode 34A forms a retention capacitor with the source-drain electrode 22B, and the Cs line 34 is connected to the Cs electrode 34A and extends in the X direction.

Here, the connection hole 41H is formed for each of the pixels 10P, and the gate electrode 32A is electrically connected to the leading line 33 through the connection hole 41H. In other words, in place of the gate electrode 32A in the same layer as that of the scanning line (the scanning line 32), the leading line 33 lower in layer than the gate electrode 32A is provided. This makes it possible to suppress occurrence of a leakage between wirings. One reason for this will be described below.

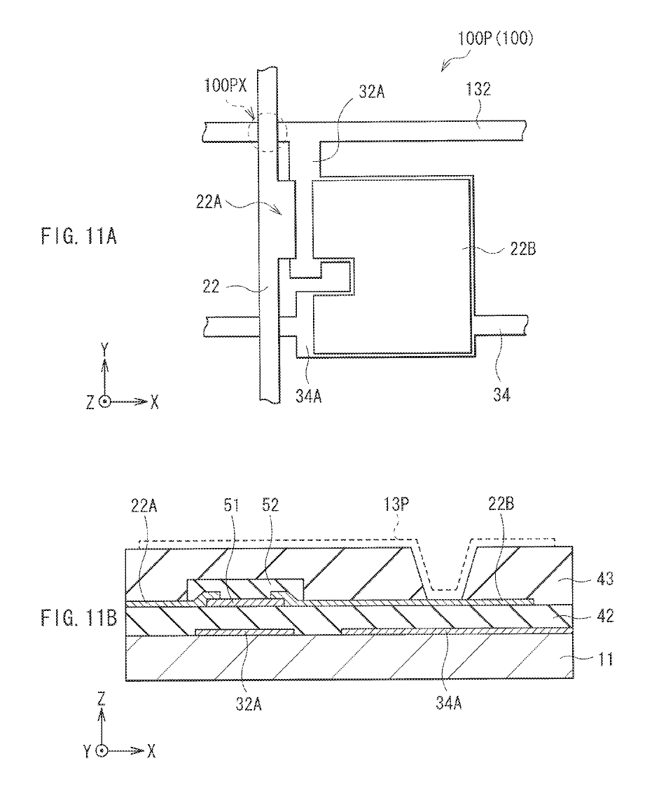

FIGS. 11A and 11B each illustrate a configuration of one of pixels 100P of the display unit 100 according to the comparative example. FIG. 11A and FIG. 11B illustrate a plane configuration and a cross-sectional configuration, respectively. The display unit 100 has the scanning line 132 which is in the same layer as that of the gate electrode 32A, and the scanning line 132 extends in an X direction. Therefore, an intersecting section 100PX at which a signal line 22 intersects the scanning line 132 at right angles has only a gate insulating film 42 between the scanning line 132 and the signal line 22. Such an intersecting section between the wirings may cause occurrence of a leakage.

In contrast, at an intersecting section 10PX where the leading line 33 and the scanning line 32 intersect (FIG. 10A), the first interlayer insulating film 41 is provided between the leading line 33 and the scanning line 32, in addition to the gate insulating film 42. This improves an insulation property between the leading line 33 and the scanning line 32, making it possible to suppress occurrence of a leakage.

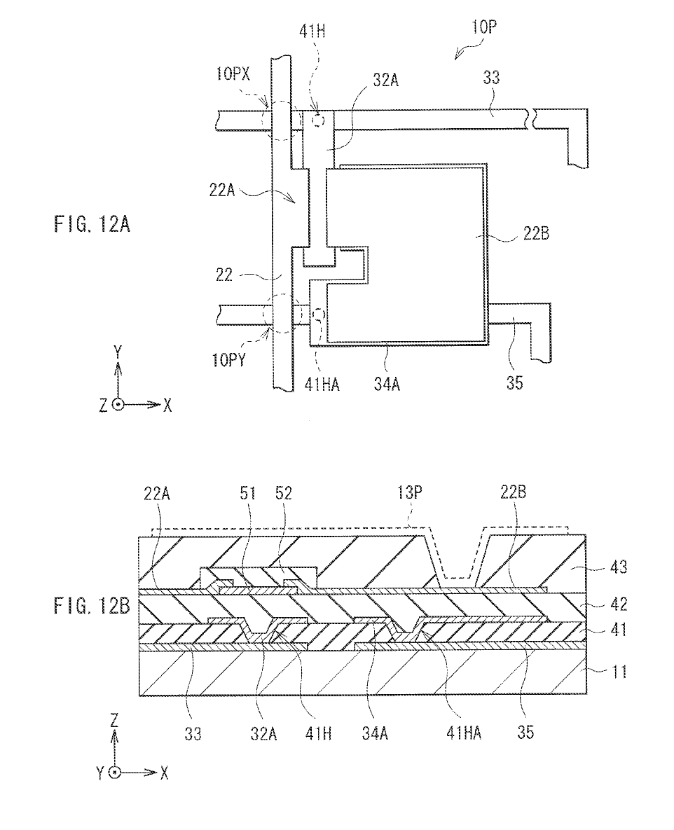

As illustrated in FIGS. 12A and 12B, a Cs line (a Cs line 35) may be provided in the same layer as that of the leading line 33, and the Cs line 35 may be electrically connected to the Cs electrode 34A through a connection hole 41HA of the first interlayer insulating film 41. At this moment, the Cs line 35 may be bent from the X direction to the Y direction, in a manner similar to the leading line 33. By providing the Cs line 35 lower in layer than the gate electrode 32A in this manner, the gate insulating film 42 and the first interlayer insulating film 41 are interposed between the Cs line 35 and the signal line 22 at an intersecting section (an intersecting section 10PY) between the Cs line 35 and the signal line 22 as well. Therefore, it is possible to prevent the occurrence of a leakage in the intersecting section between the wirings more effectively. It is to be noted that FIG. 12A illustrates a plane configuration and FIG. 12B illustrates a cross-sectional configuration, of one of the pixels 10P.

### Second Embodiment

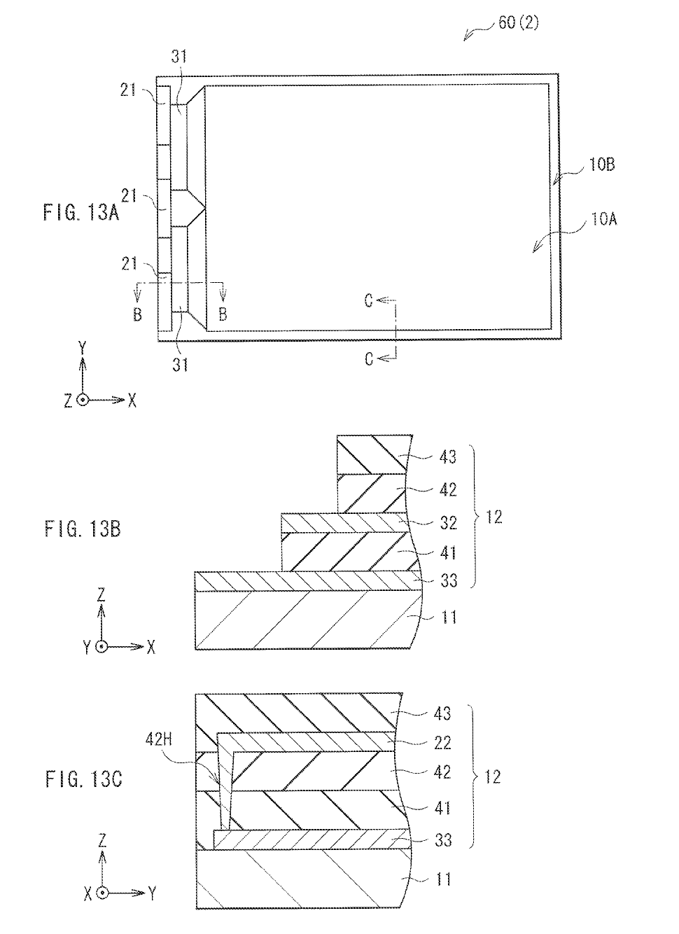

FIGS. 13A to 13C each illustrate a configuration of a TFT substrate 60 of a display unit (a display unit 2) according to a second embodiment of the technology, together with the signal-line driving circuit 21 and the scanning-line driving circuit 31. FIG. 13A illustrates a plane configuration, FIG. 13B illustrates a cross-sectional configuration taken along a line B-B of FIG. 13A, and FIG. 13C illustrates a cross-sectional configuration taken along a line C-C of FIG. 13A. In the display unit 2, the signal line 22 is electrically connected to the leading line 33. Otherwise, the display unit 2 has a configuration, functions, and effects similar to those of the display unit 1 of the first embodiment.

The wiring layer 12 of the TFT substrate 60 includes the leading line 33 (a third wiring), the first interlayer insulating film 41, the scanning line 32 (a first wiring), the gate insulating film 42, the signal line 22 (a second wiring), and the second interlayer insulating film 43 in this order from the side where the substrate 11 is provided. The signal line 22 is electrically connected to the leading line 33 through a connection hole 42H provided in the peripheral region 10B (FIGS. 13B and 13C). The connection hole 42H passes through the gate insulating film 42 and the first interlayer insulating film 41. The connection holes 42H may be provided, for example, along a lower side (a long side) of the substrate 11 (not illustrated).

The leading line 33 extends from the connection hole 42H in the Y direction (in an upward direction on a sheet surface of the figure), and then bends in an X direction (in a leftward direction on the sheet surface) (not illustrated). Therefore, at one side (a left short side on the sheet surface) of the substrate 11, the leading line 33 extends in the X direction and exits the display region with the scanning line 32. In other words, the signal-line driving circuit 21 and the scanning-line driving circuit 31 are allowed to be gathered at a short side of the substrate 11. The signal-line driving circuit 21 may be displaced from the scanning-line driving circuit 31 to be disposed further outward from the display region (FIG. 13A), or may be disposed to be aligned with the scanning-line driving circuit 31 (not illustrated). In the display unit 2, the signal-line driving circuit 21 and the scanning-line driving circuit 31 are gathered at a short side of the substrate 11. Thus, in one embodiment where the display unit 2 is a flexible display, a long side of the substrate 11 moves freely, and flexibility further improves.

### [Modification 3]

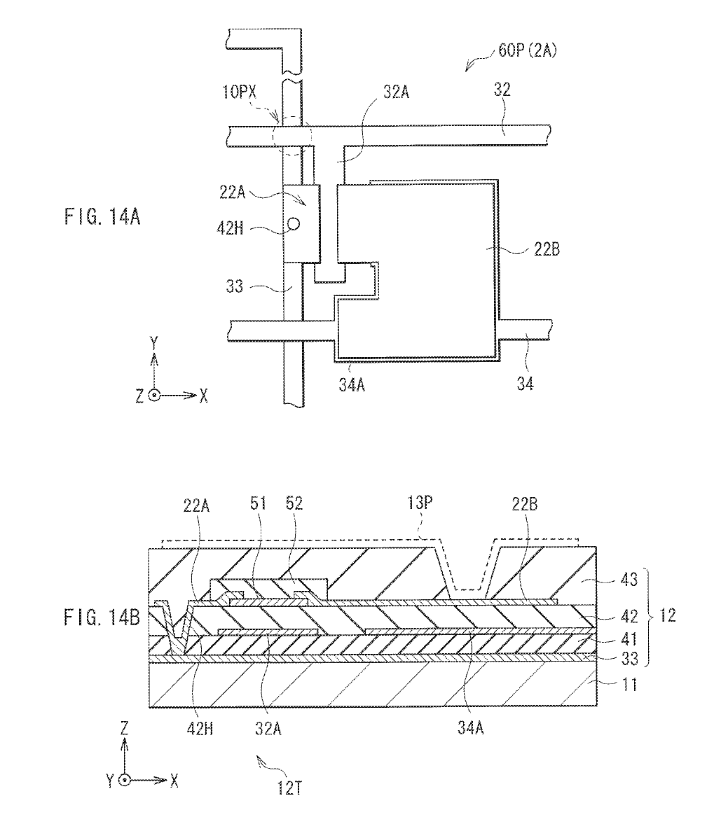

FIGS. 14A and 14B each illustrate a configuration of one of pixels 60P of a display unit (a display unit 2A) according to a modification 3 of the second embodiment. FIG. 14A and FIG. 14B illustrate a plane configuration and a cross-sectional configuration, respectively. In the display unit 2A, the leading line 33 is electrically connected to the source-drain electrode 22A of the TFT 12T, and provided for each of the pixels 60P. In other words, in place of the signal line (the signal line 22) provided in the same layer as that of the source-drain electrode 22A, the leading line 33 lower in layer than the source-drain electrode 22A is provided. Otherwise, the display unit 2A has a configuration, functions, and effects similar to those of the display unit 2 of the second embodiment.

In the display unit 2A, the connection hole 42H is provided for each of the pixels 60P, and the source-drain electrode 22A of the TFT 12T and the leading line 33 are electrically connected through the connection hole 42H. The connection hole 42H is provided to pass through the gate insulating film 42 and the first interlayer insulating film 41. At the intersecting section 10PX of the scanning line 32 and the leading line 33, the first interlayer insulating film 41 is interposed therebetween. Since the thickness of the first interlayer insulating film 41 can be made larger than that of the gate insulating film 42, it is possible to prevent the occurrence of a leakage in the intersecting section 10PX.

Any of the display units 1, 1A, 1B, 2, and 2A may be applied to, for example, an electronic apparatus exemplified by application examples 1 to 6 described below.

### Application Example 1

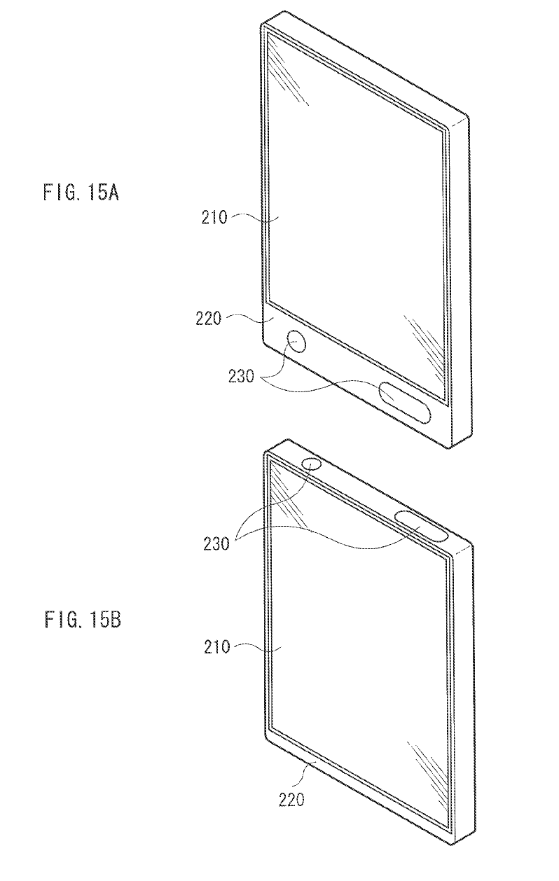

FIGS. 15A and 15B each schematically illustrate an appearance of an electronic book. The electronic book may include, for example, a display section 210, a non-display section 220, and an operation section 230. The display section 210 is configured using any one of the above-described display units 1, 1A, 1B, 2, and 2A. The operation section 230 may be formed either on the same surface as a surface (a front surface) of the display section 210 as illustrated in FIG. 15A, or on a surface (a top surface) different from the surface of the display section 210 as illustrated in FIG. 15B.

### Application Example 2

FIG. 16 schematically illustrates an appearance of a television receiver. The television receiver may include, for example, an image-display screen section 300 that includes a front panel 310 and a filter glass 320. The image-display screen section 300 is configured using any one of the above-described display units 1, 1A, 1B, 2, and 2A.

### Application Example 3

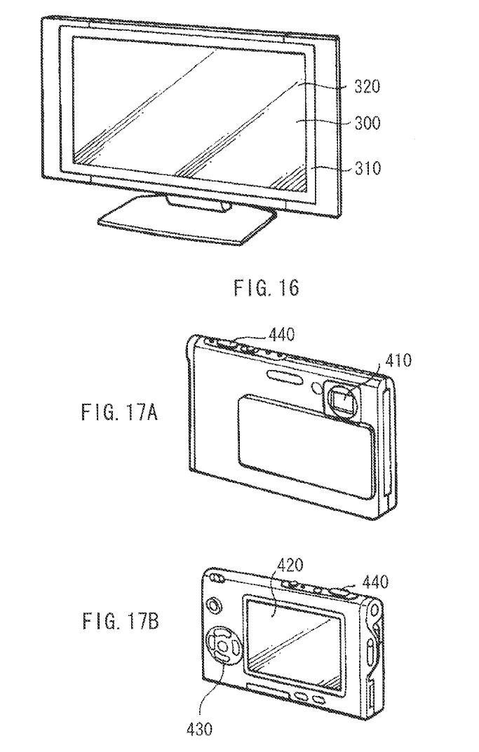

FIGS. 17A and 17B each schematically illustrate an appearance of a digital camera. The digital camera may include, for example, a flash emitting section 410, a display section 420, a menu switch 430, and a shutter release 440. The display section 420 is configured using any one of the above-described display units 1, 1A, 1B, 2, and 2A.

### Application Example 4

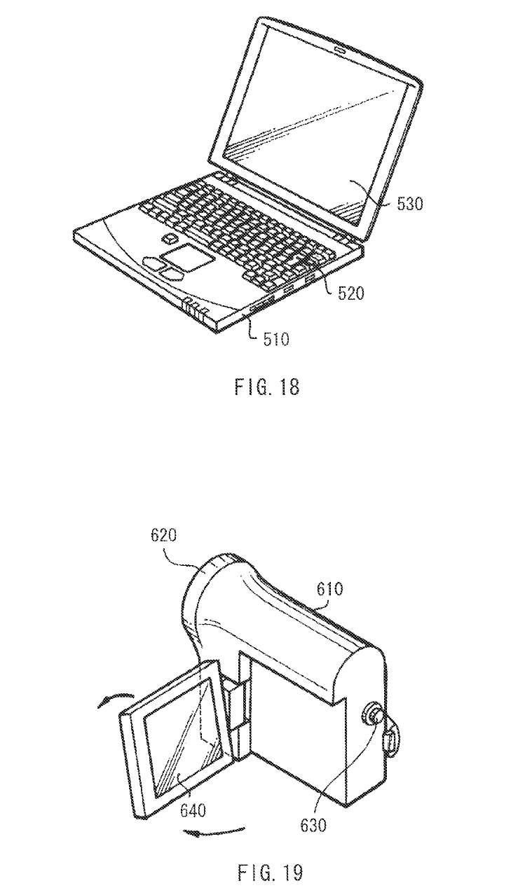

FIG. 18 schematically illustrates an appearance of a laptop computer. The laptop computer may include, for example, a main body section 510, a keyboard 520 provided to enter characters and the like, and a display section 530 displaying an image. The display section 530 is configured using any one of the above-described display units 1, 1A, 1B, 2, and 2A.

### Application Example 5

FIG. 19 schematically illustrates an appearance of a video camera. The video camera may include, for example, a main body section 610, a lens 620 disposed on a front face of the main body section 610 to shoot an image of a subject, a start/stop switch 630 used in shooting, and a display section 640. The display section 640 is configured using any one of the above-described display units 1, 1A, 1B, 2, and 2A.

### Application Example 6

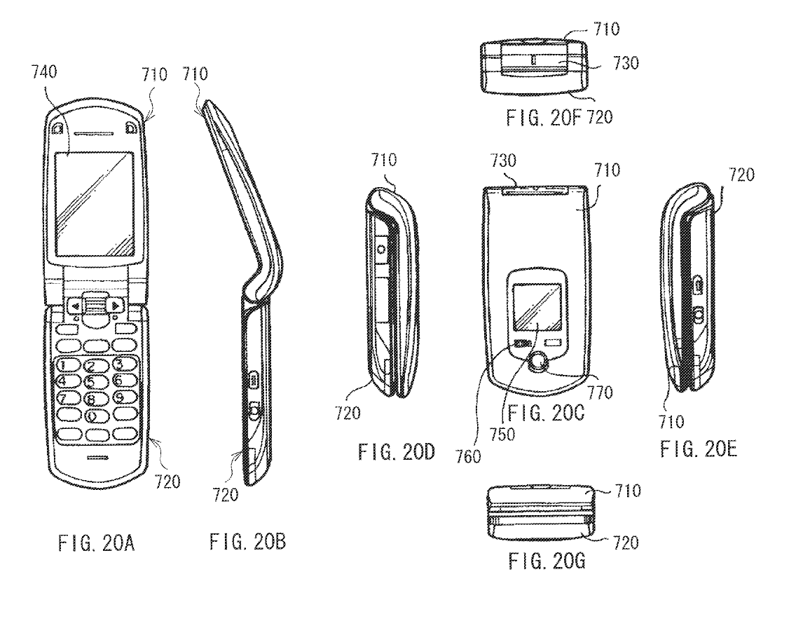

FIGS. 20A to 20G each schematically illustrate an appearance of a portable telephone. The portable telephone may be, for example, a unit in which an upper housing 710 and a lower housing 720 are connected by a coupling section (a hinge section) 730, and may include a display 740, a sub-display 750, a picture light 760, and a camera 770. At least one of the display 740 and the sub-display 750 is configured using any one of the above-described display units 1, 1A, 1B, 2, and 2A. The term “portable telephone” as used herein is intended broadly to encompass a portable terminal such as smartphone.

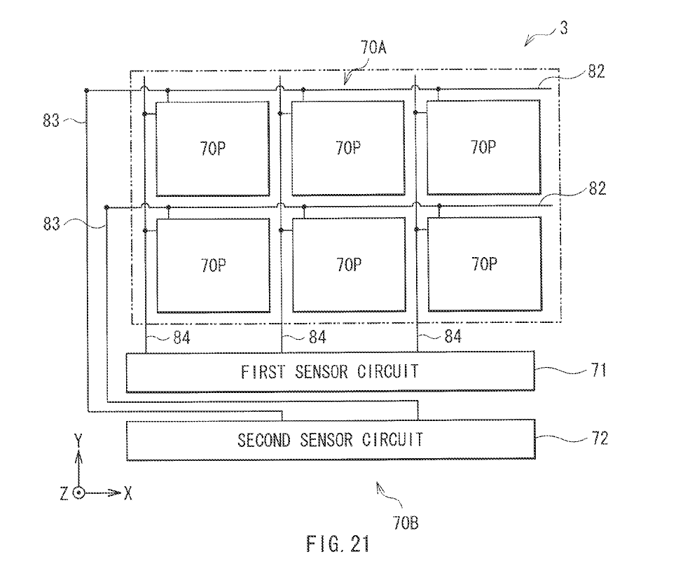

The technology has been described with reference to the example embodiments, the example modifications, and the application examples, but is not limited thereto and may be variously modified. For example, in the above-described embodiments, the example modifications, and the application examples, the signal transmission unit (the display units 1, 1A, 1B, 2, and 2A) that performs, of the input and the output of signals, the output has been described. However, the technology is applicable to, for example, a signal transmission unit (a signal input device 3) that performs the input of signals as illustrated in FIG. 21. The signal input device 3 may be, for example, a touch panel, and may have an input region 70A (a signal transmission section) in which a plurality of positional information detection regions 70P (unit regions) are arranged in a matrix. In a peripheral region 70B around the input region 70A, a first sensor circuit 71 (a first peripheral circuit) and a second sensor circuit 72 (a second peripheral circuit) may be provided. A plurality of wirings 84 extending in the Y direction may be electrically connected to the first sensor circuit 71, and a plurality of wirings 82 extending in the X direction may be electrically connected to the second sensor circuit 72 through wirings 83.

Further, with reference to FIGS. 10A, 10B, 11A, 11B, 14A and 14B, the TFT 12T of a bottom-gate type has been described, but the TFT 12T may be of a top-gate type in one embodiment. Furthermore, in the above-described embodiments, the example modifications, and the application examples, the display unit of an active matrix type having the TFT 12T for every pixel has been described, but a display unit of a passive matrix type may be adopted in one embodiment.

The material, the thickness, the film formation method, and the film formation condition of each layer described in the above-described embodiments, the example modifications, and the application examples are not limited. Any other materials, thicknesses, film formation methods, and film formation conditions may be adopted.

Also, while the example embodiments, the example modifications, and the application examples are described with specific reference to the configurations of the respective display units 1, 1A, 1B, 2, and 2A, one or more layers other than the layers described above may be further provided.

Furthermore, the technology encompasses any possible combination of some or all of the various embodiments, the modifications, and the application examples described herein and incorporated herein.

Accordingly, it is possible to achieve at least the following configurations from the above-described example embodiments, the example modifications, and the application examples of the disclosure.

(1) A display unit comprising:

a display region in which are disposed
pixel circuits,
a first wiring line connected to a given one of the pixel circuits,
a second wiring line connected to the given one of the pixel circuits, and
a third wiring line disposed in a different layer than the second wiring line and connected to the second wiring line; and

a peripheral region,

wherein the first wiring line and the third wiring line extend out of the display region into the peripheral region.

(2) The display unit as described in (1),

wherein a first peripheral circuit for communicating with the first wiring line and a second peripheral circuit for communicating with the second wiring line are disposed in the peripheral region, and

wherein the first wiring line is connected to the first peripheral circuit and the third wiring line is connected to the second peripheral circuit.

(3) The display unit as described in (1),

wherein the third wiring line and the first wiring line exit the display region on a same side of the display region.

(4) The display unit as described in (1),

wherein the third wiring line and the first wiring line extend in directions substantially parallel to each other as they exit the display region.

(5) The display unit as described in (1),

wherein the first wiring line is a signal line that provides a video signal to the given one of the pixel circuits and the second wiring line is a scanning line that provides a scanning signal for controlling introduction of the video signal into the given one of the pixel circuits.

(6) The display unit as described in (1),

wherein the second wiring line is a signal line that provides a video signal to the given one of the pixel circuits and the first wiring line is a scanning line that provides a scanning signal for controlling introduction of the video signal into the given one of the pixel circuits.

(7) The display unit as described in (1),

wherein the first wiring line is a signal line that provides a video signal to the given one of the pixel circuits and the second wiring line is a gate electrode of a transistor of the given one of the pixel circuits.

(8) The display unit as described in (1), wherein

the first wiring line extends from the peripheral region towards the display region in a first direction, and

the third wiring line extends from the peripheral region towards the display region in the first direction, then, in the display region, turns to extend in a second direction perpendicular to the first direction.

(9) The display unit as described in (8),

wherein the second wiring line extends in the display region in the second direction and is connected to the third wiring line via a connection hole located at a side of the display region that is different from the side of the display region through which the first wiring line exits the display region.

(10) The display unit as described in (2), wherein

the first wiring line extends from the first peripheral circuit towards the display region in a first direction, and

the third wiring line extends from the second peripheral circuit towards the display region in the first direction, then, in the display region, turns to extend in a second direction perpendicular to the first direction.

(11) The display unit as described in (2),

wherein the first peripheral circuit and the second peripheral circuit are disposed in a portion of the peripheral region that is adjacent to a same side of the display region.

(12) The display unit as described in (11),

wherein the portion of the peripheral region in which the first peripheral circuit and the second peripheral circuit are disposed is adjacent to a longitudinal side of the display device.

(13) The display unit as described in (11),

wherein the portion of the peripheral region in which the first peripheral circuit and the second peripheral circuit are disposed is adjacent to a short side of the display device.

(14) The display unit as described in (1),

wherein the display unit is a flexible display unit.

(15) The display unit as described in (1),

wherein the given one of the pixel circuits includes an organic light emitting element, a storage capacitor, a drive transistor for providing a driving current to the organic light emitting element whose current depends on a potential stored in the storage capacitor, and a write transistor for writing a signal potential into the storage capacitor, and

wherein one of the first wiring line and the second wiring line is connected to a gate electrode of the write transistor and the other one of the first wiring line and the second wiring line is connected to a current electrode of the write transistor.

(16) The display unit as described in (2), wherein

the third wiring line is disposed on a substrate,

an insulating layer is disposed on the third wiring line,

the second wiring line is disposed on the insulating layer and connected to the third wiring line via a connection hole,

a second insulating layer is disposed on the second wiring line,

the first wiring line is disposed on the second insulating layer,

the pixel circuits are disposed on the second insulating layer in the display region and the given one of the pixel circuits is connected to the second wiring line and the first wiring line,

the first peripheral circuit and the second peripheral circuit are disposed on the substrate in the peripheral region adjacent the display region, and

the first wiring line is connected to the first peripheral circuit and the third wiring line is connected to the second peripheral circuit.

(17) An electronic apparatus comprising:

an active region in which are disposed:
active units,
a first wiring line connected to a given one of the active units,
a second wiring line connected to the given one of the active units, and
a third wiring line disposed in a different layer than the second wiring line and connected to the second wiring line; and

a peripheral region,

wherein the first wiring line and the third wiring line extend out of the active region into the peripheral region.

(18) The electronic apparatus as described in (17),

wherein a first peripheral circuit for communicating with the first wiring line and a second peripheral circuit for communicating with the second wiring line are disposed in the peripheral region, and

wherein the first wiring line is connected to the first peripheral circuit and the third wiring line is connected to the second peripheral circuit.

(19) The electronic apparatus as described in (18), wherein

the active region is a touch panel input region,

the active units are positional information detection units configured to detect a position of an input device, and

the first peripheral circuit and the second peripheral circuit are sensor circuits.

(20) A signal transmission unit, including:

a first wiring extending in a first direction;

a second wiring provided in a layer different from a layer in which the first wiring is provided; and

a third wiring provided in a layer different from the layer in which the second wiring is provided, the third wiring being electrically connected to the second wiring, and at least a part of the third wiring extending in the first direction.

(21) The signal transmission unit according to (20), further including a substrate on which the first wiring, the second wiring, and the third wiring are provided,

wherein the first wiring and the third wiring are taken out from one side of the substrate.

(22) The signal transmission unit according to (21), further including:

a first peripheral circuit to which the first wiring is electrically connected; and

a second peripheral circuit to which the third wiring is electrically connected,

wherein the first peripheral circuit and the second peripheral circuit are provided at the one side of the substrate.

(23) The signal transmission unit according to any one of (20) to (22), wherein the second wiring extends in a second direction that intersects the first direction.
(24) The signal transmission unit according to (23), further including a plurality of unit regions,

wherein the first wiring includes a plurality of first wirings and the second wiring includes a plurality of second wirings, and the unit regions are each provided at an intersection of each of the first wirings and each of the second wirings.

(25) The signal transmission unit according to any one of (20) to (24), wherein the third wiring extends in a second direction that intersects the first direction, and is bent to extend in the first direction.
(26) The signal transmission unit according to any one of (20) to (25), further including a plurality of unit regions,

wherein the second wiring is provided for each of the unit regions.

(27) The signal transmission unit according to any one of (20) to (26), further including a first insulating film having a connection hole and provided between the second wiring and the third wiring,

wherein the second wiring is electrically connected to the third wiring through the connection hole of the first insulating film.

(28) The signal transmission unit according to (27), further including a second insulating film provided between the second wiring and the first wiring,

wherein the third wiring, the first insulating film, the second wiring, the second insulating film, and the first wiring are provided in this order.

(29) The signal transmission unit according to (27), further including a second insulating film provided between the second wiring and the third wiring,

wherein the third wiring, the first insulating film, the first wiring, the second insulating film, and the second wiring are provided in this order.

(30) The signal transmission unit according to (21), wherein the substrate includes a flexible substrate.
(31) The signal transmission unit according to (22), further including a plurality of unit regions structuring a signal transmission section,

wherein the second peripheral circuit is disposed further outward of the signal transmission section than the first peripheral circuit.

(32) The signal transmission unit according to (22), further including a plurality of unit regions structuring a signal transmission section,

wherein the first peripheral circuit and the second peripheral circuit are disposed side-by-side with respect to the signal transmission section.

(33) The signal transmission unit according to (21), wherein the substrate includes a rectangular substrate having a long side and a short side, and the first wiring and the third wiring are taken out from the long side of the substrate.
(34) The signal transmission unit according to (21), wherein the substrate includes a rectangular substrate having a long side and a short side, and the first wiring and the third wiring are taken out from the short side of the substrate.
(35) The signal transmission unit according to any one of (20) to (34), wherein the first wiring is a signal line, and the second wiring is a scanning line.
(36) The signal transmission unit according to any one of (20) to (34), wherein the first wiring is a scanning line, and the second wiring is a signal line.
(37) The signal transmission unit according to (26), further including:

a thin film transistor provided for each of the unit regions; and

a capacitor line provided in the same layer as the third wiring, at least a part of the capacitor line extending in the first direction,

wherein the first wiring is a scanning line, and the second wiring is a gate electrode of the thin film transistor.

(38) A display unit with a display section and a signal transmission unit, the signal transmission unit including:

a first wiring extending in a first direction;

a second wiring provided in a layer different from a layer in which the first wiring is provided; and

a third wiring provided in a layer different from the layer in which the second wiring is provided, the third wiring being electrically connected to the second wiring, and at least a part of the third wiring extending in the first direction.

(39) An electronic apparatus with a signal transmission unit, the signal transmission unit including:

a first wiring extending in a first direction;

a second wiring provided in a layer different from a layer in which the first wiring is provided; and

a third wiring provided in a layer different from the layer in which the second wiring is provided, the third wiring being electrically connected to the second wiring, and at least a part of the third wiring extending in the first direction.

The disclosure contains subject matter related to that disclosed in Japanese Priority Patent Application JP 2012-94562 filed in the Japan Patent Office on Apr. 18, 2012, the entire content of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A display unit comprising:
a display region in which are disposed
pixel circuits,
a first wiring line connected to a given one of the pixel circuits,
a second wiring line connected to the given one of the pixel circuits, and
a third wiring line disposed in a different layer than the second wiring line and connected to the second wiring line; and
a peripheral region,
wherein the first wiring line and the third wiring line extend out of the display region into the peripheral region.

2. The display unit of claim 1,
wherein a first peripheral circuit for communicating with the first wiring line and a second peripheral circuit for communicating with the second wiring line are disposed in the peripheral region, and
wherein the first wiring line is connected to the first peripheral circuit and the third wiring line is connected to the second peripheral circuit.

3. The display unit of claim 1,
wherein the third wiring line and the first wiring line exit the display region on a same side of the display region.

4. The display unit of claim 1,
wherein the third wiring line and the first wiring line extend in directions substantially parallel to each other as they exit the display region.

5. The display unit of claim 1,
wherein the first wiring line is a signal line that provides a video signal to the given one of the pixel circuits and the second wiring line is a scanning line that provides a scanning signal for controlling introduction of the video signal into the given one of the pixel circuits.

6. The display unit of claim 1,
wherein the second wiring line is a signal line that provides a video signal to the given one of the pixel circuits and the first wiring line is a scanning line that provides a scanning signal for controlling introduction of the video signal into the given one of the pixel circuits.

7. The display unit of claim 1,
wherein the first wiring line is a signal line that provides a video signal to the given one of the pixel circuits and the second wiring line is a gate electrode of a transistor of the given one of the pixel circuits.

8. The display unit of claim 1, wherein
the first wiring line extends from the peripheral region towards the display region in a first direction, and
the third wiring line extends from the peripheral region towards the display region in the first direction, then, in the display region, turns to extend in a second direction perpendicular to the first direction.

9. The display unit of claim 8,
wherein the second wiring line extends in the display region in the second direction and is connected to the third wiring line via a connection hole located at a side of the display region that is different from the side of the display region through which the first wiring line exits the display region.

10. The display unit of claim 2, wherein
the first wiring line extends from the first peripheral circuit towards the display region in a first direction, and
the third wiring line extends from the second peripheral circuit towards the display region in the first direction, then, in the display region, turns to extend in a second direction perpendicular to the first direction.

11. The display unit of claim 2,
wherein the first peripheral circuit and the second peripheral circuit are disposed in a portion of the peripheral region that is adjacent to a same side of the display region.

12. The display unit of claim 11,
wherein the portion of the peripheral region in which the first peripheral circuit and the second peripheral circuit are disposed is adjacent to a longitudinal side of the display device.

13. The display unit of claim 11,
wherein the portion of the peripheral region in which the first peripheral circuit and the second peripheral circuit are disposed is adjacent to a short side of the display device.

14. The display unit of claim 1,
wherein the display unit is a flexible display unit.

15. The display unit of claim 1,
wherein the given one of the pixel circuits includes an organic light emitting element, a storage capacitor, a drive transistor for providing a driving current to the organic light emitting element whose current depends on a potential stored in the storage capacitor, and a write transistor for writing a signal potential into the storage capacitor, and
wherein one of the first wiring line and the second wiring line is connected to a gate electrode of the write transistor and the other one of the first wiring line and the second wiring line is connected to a current electrode of the write transistor.

16. The display unit of claim 2, wherein
the third wiring line is disposed on a substrate,
an insulating layer is disposed on the third wiring line,
the second wiring line is disposed on the insulating layer and connected to the third wiring line via a connection hole,
a second insulating layer is disposed on the second wiring line,
the first wiring line is disposed on the second insulating layer,
the pixel circuits are disposed on the second insulating layer in the display region and the given one of the pixel circuits is connected to the second wiring line and the first wiring line,
the first peripheral circuit and the second peripheral circuit are disposed on the substrate in the peripheral region adjacent the display region, and
the first wiring line is connected to the first peripheral circuit and the third wiring line is connected to the second peripheral circuit.

17. An electronic apparatus comprising:
an active region in which are disposed:
active units,
a first wiring line connected to a given one of the active units,
a second wiring line connected to the given one of the active units, and
a third wiring line disposed in a different layer than the second wiring line and connected to the second wiring line; and
a peripheral region,
wherein the first wiring line and the third wiring line extend out of the active region into the peripheral region.

18. The electronic apparatus of claim 17,
wherein a first peripheral circuit for communicating with the first wiring line and a second peripheral circuit for communicating with the second wiring line are disposed in the peripheral region, and
wherein the first wiring line is connected to the first peripheral circuit and the third wiring line is connected to the second peripheral circuit.

19. The electronic apparatus of claim 18, wherein
the active region is a touch panel input region,
the active units are positional information detection units configured to detect a position of an input device, and
the first peripheral circuit and the second peripheral circuit are sensor circuits.
